(19) United States
(12) Patent Application Publication
(10) Pub. No.: US 2011/0242902 A1
(43) Pub. Date: Oct. 6, 2011

(54) NONVOLATILE SEMICONDUCTOR MEMORY DEVICE

(75) Inventor: Makoto IWAI, Kanagawa-ken (JP)

(73) Assignee: KABUSHIKI KAISHA TOSHIBA, Tokyo (JP)

(21) Appl. No.: 13/073,365

(22) Filed: Mar. 28, 2011

(30) Foreign Application Priority Data
Mar. 30, 2010 (JP) 2010-079832

(51) Int. Cl. G11C 16/10

(52) U.S. Cl. 365/185.19

(57) ABSTRACT

A nonvolatile semiconductor memory device includes: a memory cell array including a plurality of memory cells; a plurality of word lines each connected in common to memory cells arranged in a corresponding one of rows among the plurality of memory cells; a voltage generator including a clock signal cycle controller configured to lengthen a cycle of a clock signal every time writing is performed at a stepped-up program voltage to the memory cells connected to a word line selected from the word lines, the voltage generator being configured to generate a desired output voltage by using the clock signal, wherein the clock signal cycle controller performs control in such a way that a ramp up rate for writing at the stepped-up program voltage is kept substantially equal to a ramp up rate for writing at an initial program voltage.

### CROSS-REFERENCE TO RELATED APPLICATIONS

This application is based upon and claims the benefit of priority from the prior Japanese Patent Application No. 2010-079832, filed Mar. 30, 2010, the entire contents of which are incorporated herein by reference.

### FIELD

Embodiments described herein relate generally to a nonvolatile semiconductor memory device including a voltage generation circuit.

### BACKGROUND

A NAND-type flash memory is known as an example of a nonvolatile semiconductor memory device. As a method of writing to a NAND-type flash memory, a step-up method is known in which an initial program voltage (initial Vpgm) is applied to a word line selected for writing data, and then a program voltage is applied to the word line while the program voltage is stepped up from the initial program voltage by a step-up voltage (ΔVpgm) (see Patent Document 1, for example). A memory cell stores data by use of a written state (“0” data) which is a state having a high threshold voltage with electrons injected from a channel to a charge storage layer such as a floating gate of the memory cell, and of an erased state (“1” data) which is a state having a low threshold voltage with the electrons discharged from the floating gate to the channel.

The number of sufficiently written memory cells is increased every time the program voltage incremented by the step-up voltage is applied to the selected word line. Memory cells judged as sufficiently written as a result of verification after application of the program voltage are treated as the write inhibition memory cells and channels thereof are set in a floating state in the next application of the program voltage incremented by the step-up voltage.

Accordingly, the number of memory cells having the channels controlled to be in the floating state is increased with an increase in the number of sufficiently written memory cells, whereby load capacitance of the selected word line is decreased. Every time a program voltage is applied to the selected word line, a voltage rise from the ramp up starting voltage up to the desired program voltage becomes faster. As a consequence, every time the program voltage is applied, a time during which the program voltage is applied to memory cells becomes longer. This forces charge storage layers of not-sufficiently written memory cells to receive injection of a larger than necessary amount of electrons, and thereby may degrade the reliability of the memory cells.

In this regard, there has been known the following method of adjusting a driving force of a boost circuit in increasing a boost voltage. A time (measurement time) required by a boost potential to reach a predetermined reference potential is measured using a system clock. A controller reduces an amplitude of the clock when the measurement time is shorter than time stored in advance in a ROM (see Patent Document 2, for example).

However, a voltage detection circuit for detecting such a boost voltage needs to be equipped with an operational amplifier, and a current is constantly fed to the operational amplifier during boosting. Accordingly, current consumption of the semiconductor device is increased.

### BRIEF DESCRIPTION OF THE DRAWINGS

FIG. 1 is a block diagram showing a configuration of a NAND-type nonvolatile semiconductor memory device according to an embodiment.

FIG. 2 is a circuit diagram showing a configuration of a memory cell array according to the embodiment.

FIG. 3 is a block diagram showing a configuration of a row decoder and a voltage generator according to the embodiment.

FIGS. 4A and 4B are operation flowcharts of the nonvolatile semiconductor memory device according to the embodiment.

FIG. 5 is a timing chart of the nonvolatile semiconductor memory device according to the embodiment.

FIG. 6 is a circuit diagram showing a memory cell array and a row decoder of Modification 4.

### DETAILED DESCRIPTION

In general, according to one embodiment, a nonvolatile semiconductor memory device includes: a memory cell array including a plurality of memory cells; a plurality of word lines each connected in common to memory cells arranged in a corresponding one of rows among the plurality of memory cells; a voltage generator including a clock signal cycle controller configured to lengthen a cycle of a clock signal every time writing is performed at a stepped-up program voltage to the memory cells connected to a word line selected from the word lines, the voltage generator being configured to generate a desired output voltage by using the clock signal, wherein the clock signal cycle controller performs control in such a way that a ramp up rate for writing at the stepped-up program voltage is kept substantially equal to a ramp up rate for writing at an initial program voltage.

Hereinafter, an embodiment will be described with reference to the drawings. In the following description, portions common to all the drawings are designated by common reference numerals.

### Embodiment

### Configuration of Nonvolatile Semiconductor Memory Device

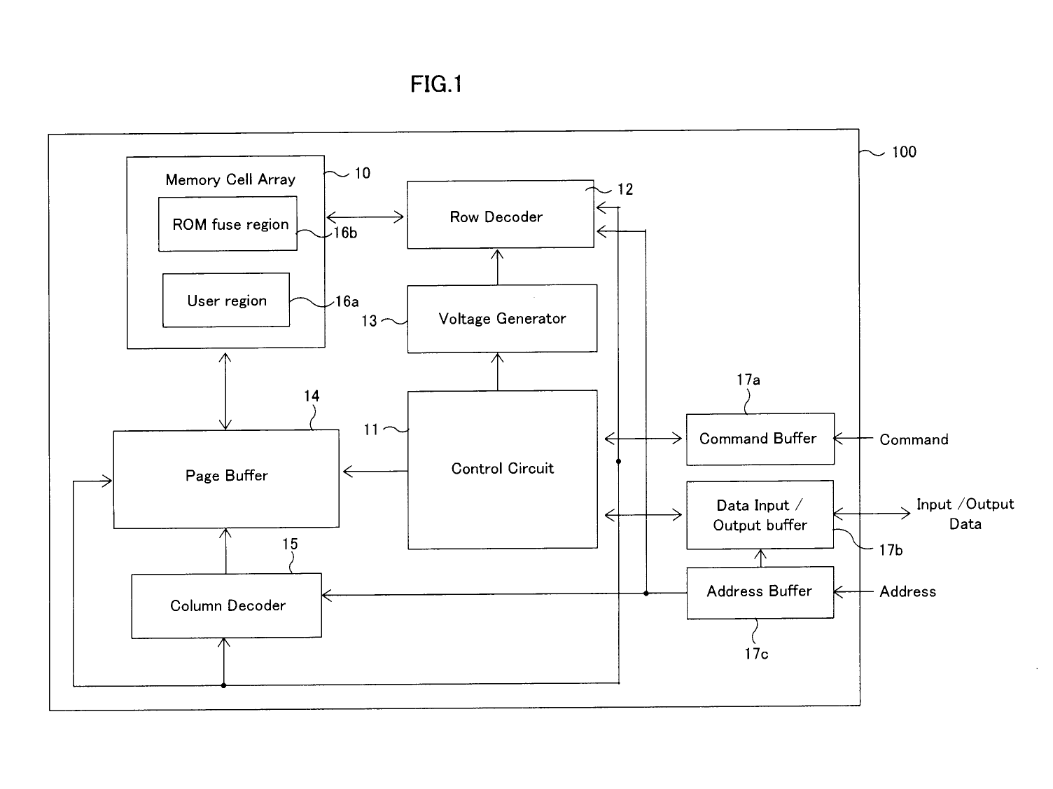

A configuration of a NAND-type nonvolatile semiconductor memory device representing an aspect of an embodiment will be described with reference to FIG. 1 to FIG. 3.

As shown in FIG. 1, a NAND-type nonvolatile semiconductor memory device 100 includes a memory cell array 10, a control circuit 11, a row decoder 12, a voltage generator 13, a page buffer 14, a column decoder 15, and the like.

### <Memory Cell Array>

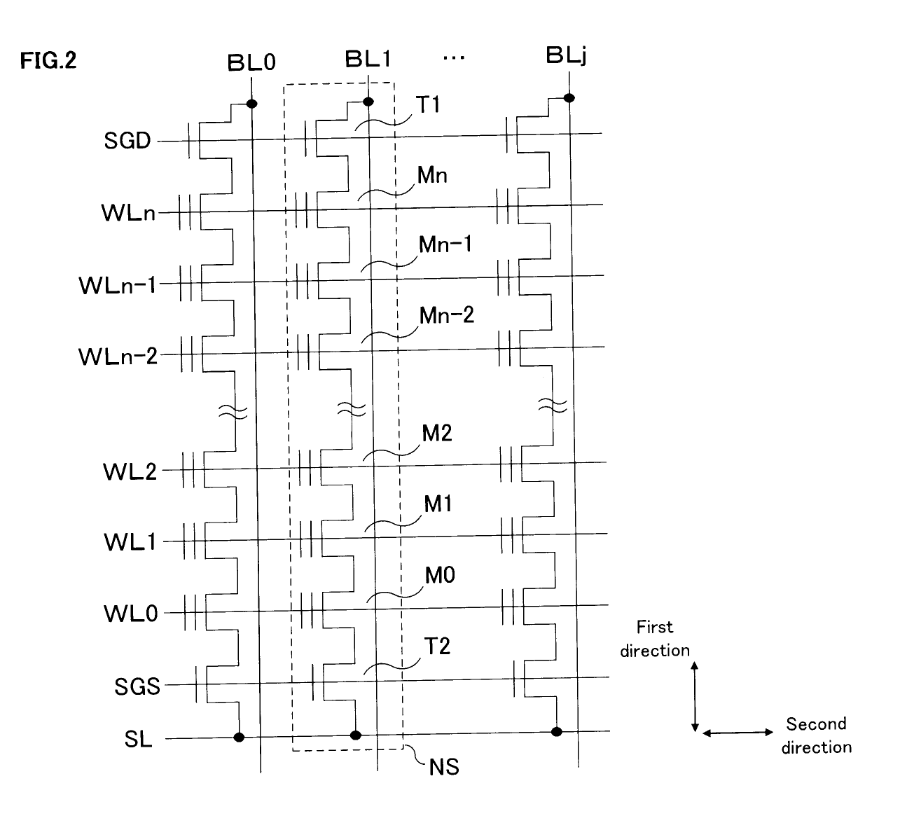

As shown in FIG. 2, the memory cell array 10 includes multiple NAND strings NS.

Multiple bit lines BL0 to BLj (j is a natural number) are disposed so as to extend in a direction (a first direction) of extension of the NAND strings NS, disposed above the NAND strings NS on a semiconductor substrate, and electrically connected to ends of the NAND strings NS. Meanwhile, multiple word lines WL0 to WLn (n is a natural number) extend in an orthogonal direction (a second direction) to the direction of extension of the NAND strings NS (which also represents a direction of extension of unillustrated active regions) and are disposed at predetermined intervals in the first direction. Multiple selection gate lines SGS and SGD are disposed in parallel respectively at both ends outside the word line WL0 and the word line WLn so as to sandwich the multiple word lines WL0 to WLn therebetween,

The NAND strings NS each include multiple memory cells M0 to Mn and first and second selection gate transistors T1 and T2. The multiple memory cells M0 to Mn are respectively formed at portions corresponding to intersections of the word lines WL and the bit lines BL and are orthogonal connected to one another in the direction of extension of the active regions. Moreover, as shown in FIG. 2, the first selection gate transistor T1 located on the side of the bit lines BL is orthogonal connected to the memory cell Mn, while the second selection gate transistor T2 located on the side of a source line SL is orthogonal connected to the memory cell M0. The NAND strings NS are connected to the source line SL in common.

As shown in FIG. 2, in the NAND strings NS, control gates of the corresponding memory cells M arranged in the second direction are respectively connected to the common word lines WL. Meanwhile, control gates of the corresponding first selection gate transistors T1 arranged in the second direction are connected to the first selection gate line SGD, and control gates of the corresponding second selection gate transistors T2 arranged in the second direction are connected to the second selection gate line SGS.

The multiple NAND strings NS are formed in a matrix inside the memory cell array 10. A set of the memory cells M in the respective NAND strings NS sharing the single word line WL collectively constitute a page that defines a unit of data reading and writing. Meanwhile, a set of the multiple NAND strings NS sharing the word lines WL collectively constitute a block that defines a unit of data erase.

As shown in FIG. 1, the memory cell array 10 is provided with a user region 16a (a storage unit 1) which can store normal data, and a ROM fuse region 16b (a storage unit 2).

Here, the ROM fuse region 16b is a region where program data for the control circuit 11 to be described later, various trimming data, and defective address data are written before shipment. These data are automatically read upon power-on, whereby the program data are set in the control circuit 11 while the trimming data and the defective address data are set in corresponding data registers and used for controlling read, write, erase and other operations.

The ROM fuse region 16b stores, as a cycle table, iteration data defining the number of iterations of programming and verification until attainment of writing data to the selected word line WL (the number of iterations is assumed to be k for the convenience of explanation), and a cycle Tm of a clock signal to be outputted from a clock signal control circuit (a clock signal cycle controller) 22 in the later-described voltage generator 13 for the m-th (m is a natural number satisfying 1≦m<k) programming.

Here, the cycle Tm of the clock signal used for the m-th programming satisfies the following formula (1) defined by use of a cycle T1 of the clock signal used for initial programming.

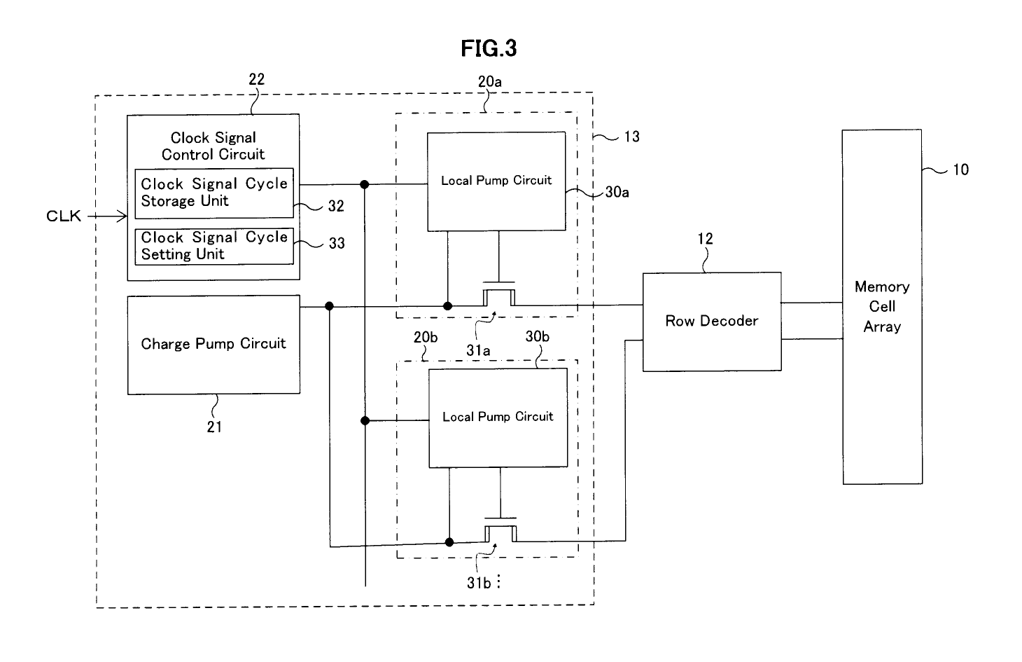

Tm={C0+(Ntotal−N1)×Cp+N1×Ci}×Vpgm1×T1/[{C0+(Ntotal−Nm)×Cp+Nm×Ci}×Vpgmm] (1)

where C0 denotes a parasitic capacitance of wiring and transistors (equivalent to transistors 31a and 31b in FIG. 3 to be described later) in the voltage generator 13, Cp denotes a capacitance for each memory cell to which “0” data is to be written, Ci denotes a capacitance for each memory cell to which “1” data is to be written, Ntotal denotes the number of the memory cells connected to one word line, N1 denotes the number of the memory cells to which “1” data is to be written in the first writing, Nm denotes the number of the memory cells to which “1” data is to be written in the m-th writing, Vpgm1 denotes an initial program voltage, and Vpgmm denotes an m-th program voltage. Here, Cp is the capacitance when a fixed potential (such as 0 V) is applied to a channel, and Ci is the capacitance when the channel is in a floating state. The capacitance value of Ci is smaller than the capacitance value of Cp. For example, the capacitance value of Ci is 20% of the capacitance value of Cp.

### <Control Circuit>

The control circuit 11 is the circuit configured to control sequences of data write, data read, and erase on the basis of commands and data supplied in accordance with an operating mode.

The control circuit 11 reads all the data in the cycle table stored in the ROM fuse region 16b in accordance with a reset signal inputted from a power-on circuit (not shown) upon power-on. The control circuit 11 stores the data as a cycle storage table in a clock signal cycle storage unit 32 in the clock signal cycle control circuit 22 to be described later. At this time, the cycle Tm of the clock signal used for the m-th programming is stored in association with write-times data m.

Moreover, the control circuit 11 sets the cycle T1 as the cycle of the clock signal outputted from the clock signal cycle control circuit 22 in an initial state. Specifically, as shown in FIG. 3, the cycle T1 of the clock signal is set in a clock signal cycle setting unit 33 in the clock signal cycle control circuit 22 to be described later.

Furthermore, when the control circuit 11 detects completion of the m-th programming and verification at the memory cells connected to the selected word line, the control circuit 11 changes the cycle of the clock signal previously set in the clock signal cycle setting unit 33 from Tm to Tm+1 for a clock signal to be used for m+1-th programming.

### <Row Decoder>

The row decoder 12 decodes a row address supplied from an address buffer 17c and selects a certain word line WL of the multiple word lines WL. The row address is positional information on the selected word line WL, and an output voltage is supplied from the voltage generator 13 to be described later to the selected word line WL.

### <Voltage Generator>

Next, details of the configuration of the voltage generator 13 will be described with reference to the block diagram of FIG. 3. The voltage generator 13 includes control gate driver circuits 20a and 20b respectively provided with local pump circuits 30a and 30b, a charge pump circuit 21, and the clock signal cycle control circuit 22. Each word line WL is provided with such a control gate driver circuit.

### <<Control Gate Driver Circuit>>

Each of the multiple control gate driver circuits 20a and 20b includes the local pump circuit 30a or 30b, and a transistor 31a or 31b. The transistor 31a or 31b used is a transistor (such as an enhancement type N-channel transistor) for high voltage.

Drains of the transistors 31a and 31b are connected to output terminals of the charge pump circuit 21. A node which connects the drains of the transistors 31a and 31b to the output terminal of the charge pump circuit 21 is connected to control terminals (not shown) of the local pump circuits 30a and 30b.

Output terminals of the local pump circuits 30a and 30b are respectively connected to control gates of the transistors 31a and 31b. Sources of the transistors 31a and 31b are respectively connected to input terminals of the row decoder 12. Output terminals of the row decoder 12 are connected to the word lines WL and the selection gate lines SGD and SGS of the memory cell array 10.

### <<Charge Pump Circuit>>

The charge pump circuit 21 generates the output voltage which is necessary for applying the program voltage to the selected word line WL, and outputs the voltage to the drains of the transistors 31a and 31b. The output voltage from the charge pump circuit 21 controls the transistors 31a and 31b and is supplied to the row decoder 12.

### <<Clock Signal Cycle Control Circuit>>

The clock signal cycle control circuit 22 includes the clock signal cycle storage unit 32 and the clock signal cycle setting unit 33. The above-described cycle storage table is stored in the clock signal cycle storage unit 32. The cycles of clock signals to be outputted to the local pump circuits 30a and 30b are set in the clock signal cycle setting unit 33.

In this embodiment, the clock signal cycle storage unit 32 is configured to store the cycle storage table, and the control circuit 11 is configured to read the data from the cycle storage table and to set the cycle in the clock signal cycle setting unit 33. However, the control circuit 11 may read the cycle Tm associated with the write-times data m from the cycle table in the ROM fuse region 16b every time programming is executed before completion of writing data to the selected word line WL. Alternatively, the cycle storage table may be stored in advance in the clock signal cycle storage unit 32.

### <Page Buffer>

The page buffer 14 incorporates multiple data latches and sense amplifiers. The data latches of the page buffer 14 perform latching of write data and latching of rewrite data in order to write the data to the memory cells. Meanwhile, the sense amplifiers perform a sensing operation for detecting the voltage variation (← [symbol] [symbol] ) of the bit lines BL and a sensing operation for verification after writing and erasing.

### <Column Decoder>

The column decoder 15 decodes a column address supplied from the address buffer 17c and selects a certain latch circuit in the page buffer 14.

### (Writing Operation of Nonvolatile Semiconductor Memory Device)

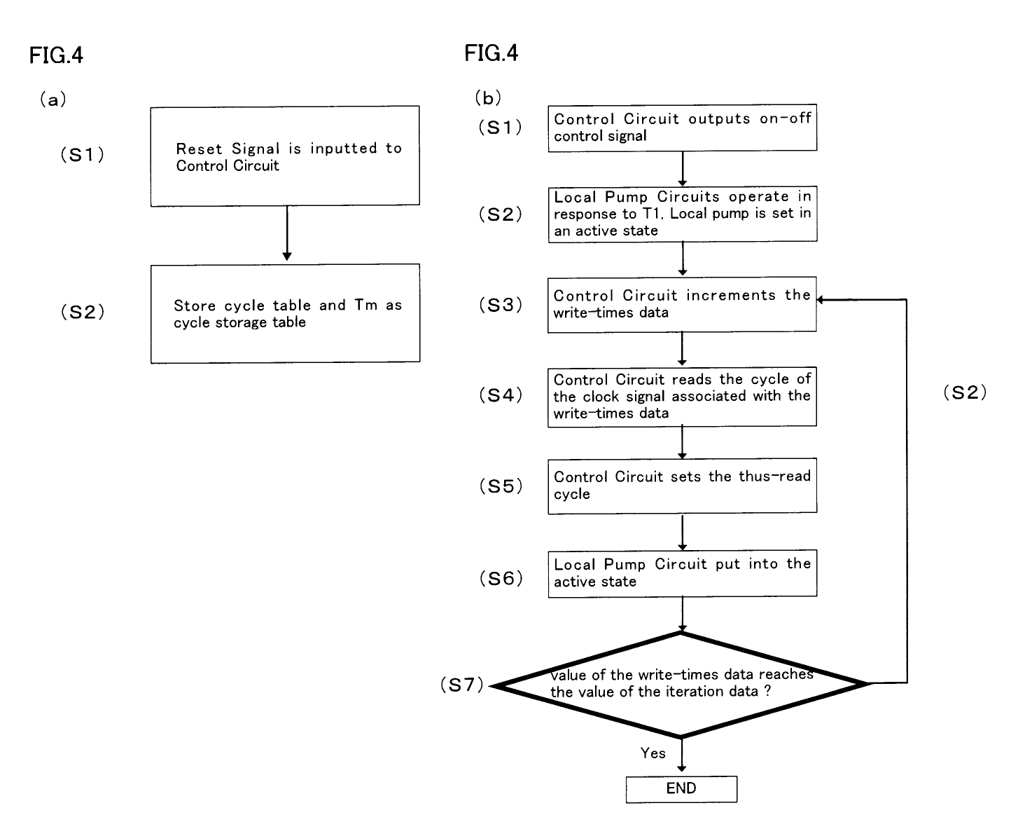

Next, a writing operation of the NAND-type nonvolatile semiconductor memory device according to the embodiment will be described with reference to FIG. 1, FIG. 3, and flowcharts in FIGS. 4A and 4B. FIG. 4A is an operation flowchart of the nonvolatile semiconductor memory device upon power-on, and FIG. 4B is an operation flowchart of the nonvolatile semiconductor memory device in writing.

### [Operation of Nonvolatile Semiconductor Memory Device Upon Power-on]

As shown in FIG. 4A, when the power is supplied to the NAND-type nonvolatile semiconductor memory device in step S1, a reset signal is inputted from the power-on circuit (not shown) to the control circuit 11.

Then, in step S2, the control circuit 11 reads the data in the cycle table from the ROM fuse region 16b in the memory cell array 10, and stores the cycle Tm of the clock signal used for the m-th programming in association with the write-times data m in the clock signal cycle storage unit 32 as the cycle storage table.

Thereafter, the control circuit 11 sets the write-times data to “1” and sets the cycle of the clock signal to the cycle T1 in the clock signal cycle setting unit 33.

### [Operation of Nonvolatile Semiconductor Memory Device in Writing to Word Line]

As shown in FIG. 4B, when the control circuit 11 receives a data write request via a command buffer 17a in step S1, the control circuit 11 outputs on-off control signals to the local pump circuits 30a and 30b to control the operations of the local pump circuits 30a and 30b.

In step S2, the local pump circuits 30a and 30b operate in response to the clock signal at the cycle T1 which is set in the clock signal cycle control setting unit 33. The local pump 30a configured to control the transistor 31a for the selected word line is set in an active state while the local pump 30b configured to control the transistor 31b for an unselected word line is set in an inactive state. When the transistor 31a for the selected word line is set in an active state, the output voltage boosted by the charge pump circuit 21 is supplied to the word line to gradually ramp up a voltage of the selected word line up to the desired program voltage.

In step S3, when the control circuit 11 detects completion of the first programming and verification at the memory cells connected to the selected word line, the control circuit 11 increments the write-times data “1” set in the clock cycle setting unit 33.

Then, in step S4, the control circuit 11 reads the cycle T2 of the clock signal associated with the write-times data “2” incremented in step S3.

In step S5, the control circuit 11 sets the thus-read cycle T2 as the cycle of a clock signal in the clock signal cycle storage unit 32. In this way, the clock signal at the cycle T2 generated by the clock signal cycle control circuit 22 is outputted to the control gate driver circuit 20a and 20b.

In step S6, in response to the clock signal at the cycle T2 set in the clock signal cycle setting unit 33, the local pump circuit 30a put into the active state as in step S2 operates to control the transistor 31a, to supply the output voltage boosted by the charge pump circuit 21 to the word line, and to gradually ramp up the voltage of the selected word line up to the desired program voltage.

In step S7, the control circuit 11 compares the write-times data with iteration data. The operation is terminated when the value of the write-times data reaches the value of the iteration data (Yes in step S7). When the value of the write-times data is below the value of the iteration data (No in step S7), the operation returns to step S3 and the procedures from step S3 to step S6 are iterated until the programming for the k-th time defined by the iteration data is executed.

### Effects of Embodiment

As described above, it is possible to provide a nonvolatile semiconductor memory device having improved reliability of memory cells without using an operating amplifier. The effect of this embodiment will be described below more specifically.

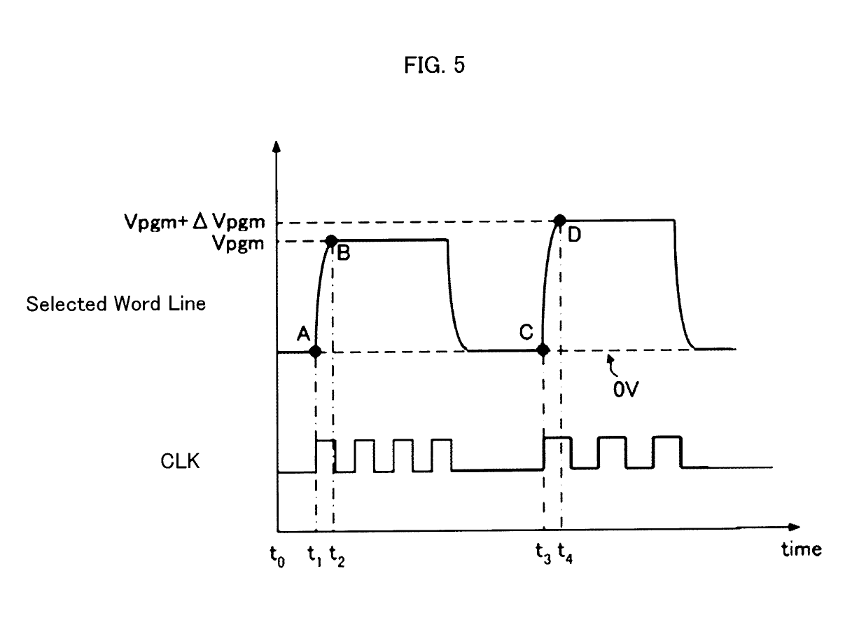

In this embodiment, the clock signal cycle control circuit 22 of the voltage generator 13 lengthens the cycle of the clock signal to be outputted to the local pump circuits 30a and 30b every time the control circuit 11 performs writing to the selected word line. A ramp up rate of the voltage of the selected word line from the ramp up starting voltage to a desired program voltage (which is an average rate expressed, for example, as the ramp up rate (=Vpgm/(t2−t1)) from a point A to a point B in a timing chart in FIG. 5, for example) depends on the cycle of the clock signal. The ramp up rate becomes slower as the cycle of the clock signal becomes longer.

Accordingly, when the writing operation is performed while the cycle of the clock signal is controlled to satisfy the aforementioned formula (1), a ramp up rate (=(Vpgm+?Vpgm)/(t4−t3)) for ramping up from a point C to a point D (from time t3 to time t4) shown in FIG. 5, for example, becomes substantially equal to the ramp up rate (=Vpgm/(t2−t1)) for ramping up from the point A to the point B (from time t1 to time t2). Hence, it is possible to prevent the ramp up rate for ramping up to the desired program voltage from becoming higher along with the decrease in load capacitance of the selected word line. For example, an error in a range from 2.5% to 5% between the time (t4−t3) and the time (t2−t1) is an acceptable error, and the ramp up rate for ramping up from the point C to the point D is substantially equal to the ramp up rate for ramping up from the point A to point B.

As a result, it is possible to provide a nonvolatile semiconductor memory device having improved reliability of memory cells, the memory device being capable of reducing an excessive amount of electrons injected to charge storage layers such as floating gates of not-sufficiently written memory cells every time a program voltage is applied.

Moreover, the nonvolatile semiconductor memory device of this embodiment does not include any operating amplifiers unlike voltage detection circuits of conventional semiconductor devices, and changes the cycle of the clock signal by use of the clock signal cycle control circuit 22. For this reason, it is not necessary to feed a current to the nonvolatile semiconductor memory device constantly during ramping up of the selected word line WL. Hence it is possible to reduce current consumption of the nonvolatile semiconductor memory device as compared to conventional semiconductor devices.

### (Modification 1)

In the above-described embodiment, the cycle Tm of the clock signal for the m-th programming is correlated with the cycle T1. Meanwhile, in Modification 1, an amplitude Am of the clock signal used for the m-th programming may be correlated with an amplitude A1 used for the initial programming so as to satisfy the following formula (2).

Am={C0+(Ntotal−Nm)×Cp+Nm×Ci}×Vpgmm×A1/[{C0+(Ntotal−N1)×Cp+N1×Ci}×Vpgm1] (2)

where C0 denotes a parasitic capacitance of wiring and transistors (equivalent to the transistors 31a and 31b in FIG. 3) in the voltage generator 13, Cp denotes a capacitance for each memory cell to which “0” data is to be written, Ci denotes a capacitance for each memory cell to which “1” data is to be written, Ntotal denotes the number of the memory cells connected to one word line, N1 denotes the number of the memory cells to which “1” data is to be written in the first writing, Nm denotes the number of the memory cells to which “1” data is to be written in the m-th writing, Vpgm1 denotes an initial program voltage, and Vpgmm denotes an m-th program voltage.

In Modification 1 also, the ramp up rate of the voltage on the selected word line from the ramp up starting voltage to the desired program voltage depends on the amplitude of the clock signal as similar to the case of the embodiment, whereby the ramp up rate becomes slower as the amplitude of the clock signal becomes smaller. In this way, it is possible to prevent the ramp up rate for ramping up to the desired program voltage from becoming faster along with the decrease in the load capacitance of the selected word line. As a result, it is possible to provide a nonvolatile semiconductor memory device having improved reliability of memory cells, the memory device being capable of reducing an excessive amount of electrons injected to the charge storage layers such as floating gates of not-sufficiently written memory cells every time a program voltage is applied.

Note that when writing is performed in accordance with the step-up method with the cycle of the clock signal being controlled so as to satisfy the above-mentioned formula (2), the ranp up rate during writing while stepping up the program voltage becomes substantially equal to the ramp up rate for writing with the initial program voltage.

Moreover, the nonvolatile semiconductor memory device of this example does not include any operating amplifiers unlike voltage detection circuits of conventional semiconductor devices, and changes the amplitude of the clock signal by use of the clock signal cycle control circuit 22. For this reason, it is not necessary to feed a current to the nonvolatile semiconductor memory device constantly during ramping up of the selected word line WL. Hence it is possible to reduce current consumption of the nonvolatile semiconductor memory device as compared to conventional semiconductor devices.

### (Modification 2)

The above-described embodiment is configured to slow down the ramp up rate of the voltage on the selected word line from the ramp up starting voltage to the desired program voltage by changing the cycle of the clock signal every time the program voltage is applied to the selected word line. On the other hand, in Modification 2, when the selected word line is ramped up to an intermediate voltage and then is further ramped up from the intermediate voltage to a desired program voltage, the cycle or amplitude of the clock signal may be changed so as to satisfy the formula (1) or the formula (2) during the period when the voltage is ramped up from the intermediate voltage to the desired program voltage, whereby the ramp up rate for ramping up from the intermediate voltage to the desired program voltage may be kept substantially equal.

### [Effects of Modification 2]

In Modification 2, it is possible to, for example, ramp up the selected word line and unselected word lines to the intermediate voltage, for example, and then to ramp up the selected word line from the intermediate voltage to the desired program voltage.

In this case, the voltage on channels of the write inhibition memory cells connected to the selected word line becomes high by self boosting as compared to the voltage on channels of the write inhibition memory cells connected to a selected word line that has been ramped up a desired program voltage after unselected word lines are ramped up to the intermediate voltage, for example. As a result, as compared to the case of ramping up the selected word line to the desired program voltage after the unselected word lines are ramped up to the intermediate voltage, for example, Modification 2 makes it possible to prevent erroneous writing to the write inhibition memory cells which are connected to the selected word line.

### (Modification 3)

In the above-described embodiment, the cycle Tm used for the m-th programming is constant. Instead, the cycle Tm may vary in Modification 3. For example, when the clock signal is applied K times, the m-th programming can be executed by use of a cycle Tm− where m is 1 to L (L<K) and by use of a cycle Tm+ (this cycle is longer than Tm−) where m is (L+1) to K.

For example, cycles T(m+1)− and T(m+1)+ for an (m+1)-th programming respectively satisfy the following formulae (3) and (4).

T(m+1)−=(K−L)×Vpgmm×Tm+1/{L×(Vpgmm+1−Vpgmm)} (3)

T(m+1)+=Tm+1 (4)

In this way, it is possible to prevent the ramp up rate for ramping up to the desired program voltage from becoming faster along with the decrease in the load capacitance of the selected word line. Moreover, by controlling the cycle of the clock signal for the m-th programming also, it is possible to control the ramp up rate during writing while stepping up the program voltage more accurately, and thereby to provide a nonvolatile semiconductor memory device having further improved reliability of memory cells.

### (Modification 4)

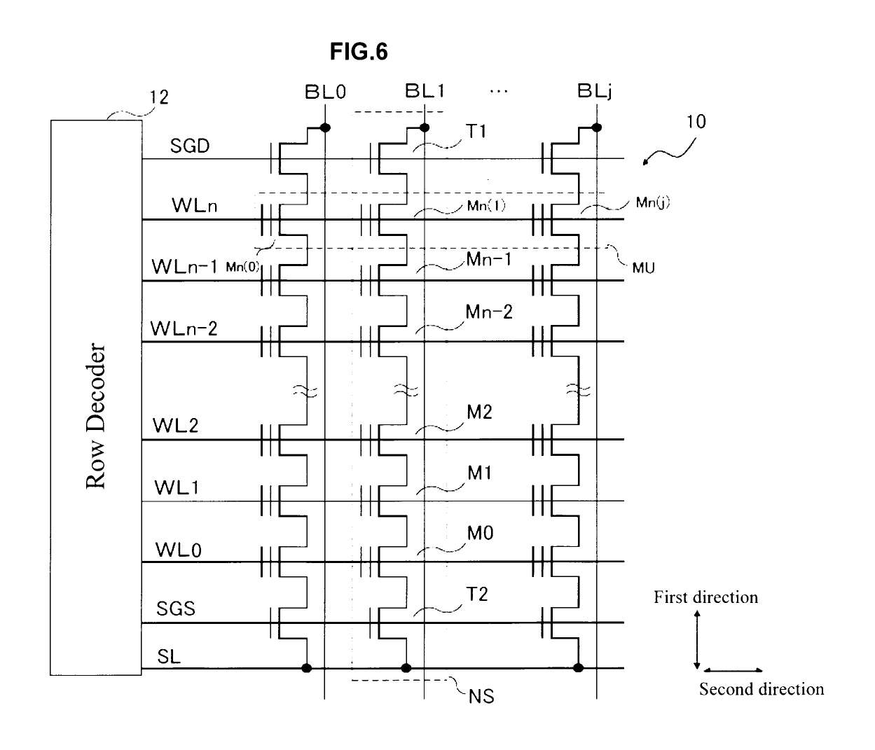

In the above-described embodiment, the control is performed when the data is written in accordance with the step-up method. On the other hand, Modification 4 is configured to perform control in accordance with a distance between each memory cell in the memory cell array 10 and the row decoder 12. The description will be given with reference to a schematic diagram in FIG. 6 while focusing on memory cells for one page connected to a word line WL, for example.

As shown in FIG. 6, a memory cell unit MU includes memory cells M for one page. For the convenience of explanation, the memory cells M in the memory cell unit MU are defined as Mn(0) to Mn(j) in accordance with the numbers of the bit lines BL.

The memory cell Mn(0) is connected to the row decoder 12. Therefore, the memory cell Mn(0) is the memory cell M closest to the row decoder 12 in the memory cell unit MU. Meanwhile, the memory cell Mn(j) is the memory cell M farthest from the row decoder 12 in the memory cell unit MU.

When the data is written to the memory cell unit MU in accordance with the step-up method, the ramp up rate during wiring while stepping up the program voltage varies among the memory cells Mn(0) to Mn(j). This is because the memory cells Mn(0) to Mn(j) vary in RC delay mainly due to resistance of the word line WL.

Therefore, the nonvolatile semiconductor memory device of Modification 4 is configured to control the cycle so that the cycle can satisfy the following formulae (5) and (6).

<Memory Cell Mn(i)> (where i is an Integer in a Range from 0 to j−1)

Tm={C0+(Ntotal−N1)×Cp+N1×Ci}/{C0+(Ntotal−Nm)×Cp+Nm×Ci}×{(Vpgm1/Vpgmn)×T1+{I1×(R0+R×i)}/Vpgmn}−{I1×(R0+R×i)}/Vpgmn (5)

where C0 denotes a parasitic capacitance of wiring and transistors (equivalent to the transistors 31a and 31b in FIG. 3) in the voltage generator 13, Cp denotes a capacitance for each memory cell to which “0” data is to be written, Ci denotes a capacitance for each memory cell to which “1” data is to be written, Ntotal denotes the number of the memory cells connected to one word line, N1 denotes the number of the memory cells to which “1” data is to be written in the first writing, Nm denotes the number of the memory cells to which “1” data is to be written in the m-th writing, Vpgm1 denotes an initial program voltage, and Vpgmm denotes an m-th program voltage. Here, Cp is the capacitance when a fixed potential (such as 0 V) is applied to a channel, and Ci is the capacitance when the channel is in a floating state. The capacitance value of Ci is smaller than the capacitance value of Cp. For example, the capacitance value of Ci is 20% of the capacitance value of Cp. Moreover, R0 denotes a WL resistance value between the row decoder and the memory cell Mn(0) next to the row decoder in the memory cell array 10, R denotes a WL resistance value between the memory cells such as the WL resistance value between the memory cell Mn(0) and the memory cell Mn(1), and I1 denotes a current that a WL charge driver can supply.

### <Memory Cell Mn(j)>

Tm={C0+(Ntotal−N1)×Cp+N1×Ci}/{C0+(Ntotal−Nm)×Cp+Nm×Ci}×{(Vpgm1/Vpgmn)×T1+{I1×(R0+R×j)}/Vpgmn}−{I1×(R0+R×j)}/Vpgmn (6)

where C0 denotes a parasitic capacitance of wiring and transistors (equivalent to the transistors 31a and 31b in FIG. 3) in the voltage generator 13, Cp denotes a capacitance for each memory cell to which “0” data is to be written, Ci denotes a capacitance for each memory cell to which “1” data is to be written, Ntotal denotes the number of the memory cells connected to one word line, N1 denotes the number of the memory cells to which “1” data is to be written in the first writing, Nm denotes the number of the memory cells to which “1” data is to be written in the m-th writing, Vpgm1 denotes an initial program voltage, and Vpgmm denotes an m-th program voltage. Here, Cp is the capacitance when a fixed potential (such as 0 V) is applied to a channel, and Ci is the capacitance when the channel is in a floating state. The capacitance value of Ci is smaller than the capacitance value of Cp. For example, the capacitance value of Ci is 20% of the capacitance value of Cp. Moreover, R0 denotes a word line WL resistance between the row decoder and the memory cell Mn(0) closest to the row decoder in the memory cell array 10, R denotes a word line WL resistance between the adjacent memory cells (such as the word line WL resistance between the memory cell Mn(0) and the memory cell Mn(1)), and I1 denotes a current that a word line charge driver (not shown) can supply.

In this way, it is possible to perform the control without being affected by the difference in the load capacitance corresponding to the distances between the row decoder 12 and the respective memory cells in the memory cell array 10, and to equalize the ramp up rate for ramping up to the desired program voltage even in the case of writing to the memory cells connected to the selected word line WL in accordance with the step-up method. Specifically, in this modification, the difference in the ramp up rate caused by the different RC delay attributable to the distances between the row decoder 12 and the memory cells M is reduced by controlling so as to satisfy the formulae (5) and (6)

It is to be noted that the present embodiment is not limited only to the above-described embodiment and various modifications are possible at a practical stage without departing from the scope. For example, a set of circuits each formed by serially connecting a switching transistor and a resistor element may be connected in parallel between the charge pump circuit 21 and the transistors 31a and 31b of the control gate driver circuits 20a and 20b. Then, resistance values between the charge pump circuit 21 and the transistors 31a and 31b is changed by controlling on-off operations of the switching transistors; thereby, the ramp up rate of the voltage of the selected work line from the ramp up starting voltage to a desired program voltage becomes substantially equal to the ramp up rate of the voltage of the selected work line from the ramp up starting voltage at the initial stage to the desired initial program voltage. In this case, it is possible to provide multiple resistor elements to gradually change the resistance values.

Meanwhile, the embodiment has been described by using the NAND-type nonvolatile semiconductor memory device as an example. However, without limitation to the foregoing, the embodiment is also applicable to a nonvolatile semiconductor memory device incorporating a resistance random access memory (ReRAM), for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a memory cell array including a plurality of memory cells;
a plurality of word lines each connected in common to memory cells arranged in a corresponding one of rows among the plurality of memory cells;
a voltage generator including a clock signal cycle controller configured to lengthen a cycle of a clock signal every time writing is performed at a stepped-up program voltage to the memory cells connected to a word line selected from the word lines, the voltage generator being configured to generate a desired output voltage by using the clock signal,
wherein the clock signal cycle controller performs control in such a way that a ramp up rate for writing at the stepped-up program voltage is kept substantially equal to a ramp up rate for writing at an initial program voltage.

2. The nonvolatile semiconductor memory device according to claim 1,
wherein the clock signal cycle controller performs control in such a way that a ramp up rate for boosting from an intermediate voltage to the stepped-up program voltage becomes substantially equal to a ramp up rate for boosting from the initial program voltage to the intermediate voltage.

3. The nonvolatile semiconductor memory device according to claim 1, further comprising:
a control circuit; and
a clock signal cycle storage unit and a clock signal cycle setting unit provided in the clock signal cycle controller,
the clock signal cycle storage unit configured to store a cycle of a first clock signal used for m-th writing at the program voltage (m is an integer satisfying 1≦m<k where k is the number of iterations of programming and verification until attainment of writing data to the selected word line) and
the clock signal cycle setting unit configured to set therein the cycle of the first clock signal,
wherein, upon detection of completion of m-th writing, the control circuit sets in the clock signal cycle setting unit a cycle of a second clock signal used for writing at the m+1-th program voltage.

4. The nonvolatile semiconductor memory device according to claim 2, further comprising:
a control circuit; and
a clock signal cycle storage unit and a clock signal cycle setting unit provided in the clock signal cycle controller,
the clock signal cycle storage unit configured to store a cycle of a first clock signal used for m-th writing at the program voltage (m is an integer satisfying 1≦m<k where k is the number of iterations of programming and verification until attainment of writing data to the selected word line) and
the clock signal cycle setting unit configured to set therein the cycle of the first clock signal,
wherein, upon detection of completion of m-th writing, the control circuit sets in the clock signal cycle setting unit a cycle of a second clock signal used for writing at the m+1-th program voltage.

5. The nonvolatile semiconductor memory device according to claim 1,
wherein the clock signal cycle controller controls a cycle Tm of a first clock signal so that the cycle Tm satisfies the following formula relative to a cycle T1 of the clock signal used for writing at the initial program voltage:
Tm={C0+(Ntotal−N1)×Cp+N1×Ci}×Vpgm1×T1/[{C0+(Ntotal−Nm)×Cp+Nm×Ci}×Vpgmm],
where C0 denotes a parasitic capacitance of a transistor in the voltage generator; Cp denotes a capacitance for each memory cell, connected to the selected word line, to which “0” data is to be written; Ci denotes a capacitance for each memory cell to which “1” data is to be written; Ntotal1 denotes the number of the memory cells connected to one word line of the selected word lines; N1 denotes the number of the memory cells to which “1” data is to be written in the first writing; Nm denotes the number of the memory cells to which “1” data is to be written in the m-th writing; Vpgm1 denotes the initial program voltage; and Vpgmm denotes an m-th program voltage.

6. The nonvolatile semiconductor memory device according to claim 2,
wherein the clock signal cycle controller controls a cycle Tm of a first clock signal so that the cycle Tm satisfies the following formula relative to a cycle T1 of the clock signal used for writing at the initial program voltage:
Tm={C0+(Ntotal−N1)×Cp+N1×Ci}×Vpgm1×T1/[{C0+(Ntotal−Nm)×Cp+Nm×Ci}×Vpgmm],
where C0 denotes a parasitic capacitance of a transistor in the voltage generator; Cp denotes a capacitance for each memory cell, connected to the selected word line, to which “0” data is to be written; Ci denotes a capacitance for each memory cell to which “1” data is to be written; Ntotal1 denotes the number of the memory cells connected to one word line of the selected word lines; N1 denotes the number of the memory cells to which “1” data is to be written in the first writing; Nm denotes the number of the memory cells to which “1” data is to be written in the m-th writing; Vpgm1 denotes the initial program voltage; and Vpgmm denotes an m-th program voltage.

7. The nonvolatile semiconductor memory device according to claim 1,
wherein the clock signal cycle controller controls a oscillation Am of a first clock signal so that the oscillation Am satisfies the following formula relative to a oscillation A1 of the clock signal used for writing at the initial program voltage:
Am={C0+(Ntotal−N1)×Cp+N1×Ci}×Vpgm1×A1/[{C0+(Ntotal−Nm)×Cp+Nm×Ci}×Vpgmm],
where C0 denotes a parasitic capacitance of a transistor in the voltage generator; Cp denotes a capacitance for each memory cell, connected to the selected word line, to which “0” data is to be written; Ci denotes a capacitance for each memory cell to which “1” data is to be written; Ntotal1 denotes the number of the memory cells connected to one word line of the selected word lines; N1 denotes the number of the memory cells to which “1” data is to be written in the first writing; Nm denotes the number of the memory cells to which “1” data is to be written in the m-th writing; Vpgm1 denotes the initial program voltage; and Vpgmm denotes an m-th program voltage.

8. The nonvolatile semiconductor memory device according to claim 2,
wherein the clock signal cycle controller controls a oscillation Am of a first clock signal so that the oscillation Am satisfies the following formula relative to a oscillation A1 of the clock signal used for writing at the initial program voltage:
Am={C0+(Ntotal−N1)×Cp+N1×Ci}×Vpgm1×A1/[{C0+(Ntotal−Nm)×Cp+Nm×Ci}×Vpgmm],
where C0 denotes a parasitic capacitance of a transistor in the voltage generator; Cp denotes a capacitance for each memory cell, connected to the selected word line, to which “0” data is to be written; Ci denotes a capacitance for each memory cell to which “1” data is to be written; Ntotal1 denotes the number of the memory cells connected to one word line of the selected word lines; N1 denotes the number of the memory cells to which “1” data is to be written in the first writing; Nm denotes the number of the memory cells to which “1” data is to be written in the m-th writing; Vpgm1 denotes the initial program voltage; and Vpgmm denotes an m-th program voltage.

9. The nonvolatile semiconductor memory device according to claim 3,
wherein the clock signal cycle controller controls a cycle Tm of the first clock signal so that the cycle Tm satisfies the following formula relative to a cycle T1 of the clock signal used for writing at the initial program voltage:
Tm={C0+(Ntotal−N1)×Cp+N1×Ci}×Vpgm1×T1/[{C0+(Ntotal−Nm)×Cp+Nm×Ci}×Vpgmm]
where C0 denotes a parasitic capacitance of a transistor inside the voltage generation chamber; Cp denotes a capacitance for each memory cell, connected to the selected word line, to which “0” data is to be written; Ci denotes a capacitance for each memory cell to which “1” data is to be written; Ntotal1 denotes the number of the memory cells connected to one word line of the selected word lines; N1 denotes the number of the memory cells to which “1” data is to be written in the first writing; Nm denotes the number of the memory cells to which “1” data is to be written in the m-th writing; Vpgm1 denotes the initial program voltage; and Vpgmm denotes an m-th program voltage.

10. The nonvolatile semiconductor memory cell according to claim 1,
wherein the memory cell array comprises a cycle table in which a cycle of a first clock signal and write-times data m are stored in association with each other, and
upon powering on the nonvolatile semiconductor memory device, the control circuit reads all the data from the cycle table and stores the data in the clock signal cycle storage unit.

11. The nonvolatile semiconductor memory cell according to claim 2,
wherein the memory cell array comprises a cycle table in which a cycle of a first clock signal and write-times data m are stored in association with each other, and
upon powering on the nonvolatile semiconductor memory device, the control circuit reads all the data from the cycle table and stores the data in the clock signal cycle storage unit.

12. The nonvolatile semiconductor memory cell according to claim 3,
wherein the memory cell array comprises a cycle table in which a cycle of a first clock signal and write-times data m are stored in association with each other, and
upon powering on the nonvolatile semiconductor memory device, the control circuit reads all the data from the cycle table and stores the data in the clock signal cycle storage unit.

13. The nonvolatile semiconductor memory cell according to claim 4,
wherein the memory cell array comprises a cycle table in which a cycle of a first clock signal and write-times data m are stored in association with each other, and
upon powering on the nonvolatile semiconductor memory device, the control circuit reads all the data from the cycle table and stores the data in the clock signal cycle storage unit.

14. The nonvolatile semiconductor memory device according to claim 4,
wherein the clock signal cycle controller controls a cycle Tm of the first clock signal for an i-th memory cell (i is an integer satisfying 0≦i≦j) from a row decoder so that the cycle Tm satisfies the following formula relative to a cycle T1 of the clock signal used for writing at the initial program voltage:
Tm={C0+(Ntotal−N1)×Cp+N1×Ci}/{C0+(Ntotal−Nm)×Cp+Nm×Ci}×{(Vpgm1/Vpgmn)×T1+{I1×(R0+R×i)}/Vpgmn}−{I1×(R0+R×i)}/Vpgmn
where C0 denotes a parasitic capacitance of a transistor inside the voltage generation chamber; Cp denotes a capacitance for each memory cell connected to the selected word line in which “0” data is to be written; Ci denotes a capacitance for each memory cell to which “1” data is to be written; Ntotal1 denotes the number of the memory cells connected to one word line of the selected word lines; N1 denotes the number of the memory cells to which “1” data is to be written in the first writing; Nm denotes the number of the memory cells to which “1” data is to be written in the m-th writing, Vpgm1 denotes the initial program voltage; Vpgmm denotes an m-th program voltage; R0 denotes a resistance of the word line between the row decoder and a 0-th memory cell, R denotes a resistance of the word line between any adjacent ones of the memory cells; and I1 denotes a current supplied from a word line charge driver.

15. The nonvolatile semiconductor memory device according to claim 13,
wherein the clock signal cycle controller controls a cycle Tm of the first clock signal for an i-th memory cell (i is an integer satisfying 0≦i≦j) from a row decoder so that the cycle Tm satisfies the following formula relative to a cycle T1 of the clock signal used for writing at the initial program voltage:
Tm={C0+(Ntotal−N1)×Cp+N1×Ci}/{C0+(Ntotal−Nm)×Cp+Nm×Ci}×{(Vpgm1/Vpgmn)×T1+{I1×(R0+R×i)}/Vpgmn}−{I1×(R0+R×i)}/Vpgmn
where C0 denotes a parasitic capacitance of a transistor inside the voltage generation chamber; Cp denotes a capacitance for each memory cell connected to the selected word line in which “0” data is to be written; Ci denotes a capacitance for each memory cell to which “1” data is to be written; Ntotal1 denotes the number of the memory cells connected to one word line of the selected word lines; N1 denotes the number of the memory cells to which “1” data is to be written in the first writing; Nm denotes the number of the memory cells to which “1” data is to be written in the m-th writing, Vpgm1 denotes the initial program voltage; Vpgmm denotes an m-th program voltage; R0 denotes a resistance of the word line between the row decoder and a 0-th memory cell, R denotes a resistance of the word line between any adjacent ones of the memory cells; and I1 denotes a current supplied from a word line charge driver.
